(19) United States
(12) Patent Application Publication
(10) Pub. No.: US 2009/0011217 A1
(43) Pub. Date: Jan. 8, 2009

(54) Method for applying a porous glass layer

(75) Inventors: Clemens Ottermann, Hattersheim (DE); Joern Pommerehne, Loerrach (DE)

Correspondence Address: DeMont & Breyer, LLC, 100 Commons Way, Ste. 250, Holmdel, NJ, 07733, US

(73) Assignee: SCHOTT AG, 55122 Mainz (DE)

(21) Appl. No.: 12/067,021

(22) PCT Filed: Sep. 14, 2006
(86) PCT No.: PCT/EP06/08968

§ 371 Date: Sep. 19, 2008

(30) Foreign Application Priority Data
Sep. 16, 2005 (DE) 10 2005 044 522.5

(51) Int. Cl. C23C 14/10; C03C 17/00

(52) U.S. Cl. 428/310.5; 204/192.15; 204/192.11; 204/192.14; 428/304.4; 204/192.3; 428/315.5; 428/317.1

(57) ABSTRACT

The invention relates to a method for applying a porous glass layer. It is proposed to apply a porous glass layer by means of a PVD method. Porosity factor and average pore size can be varied by means of the process parameters such as pressure and deposition rate, as well as by deliberate addition of extrinsic substances.

### DESCRIPTION OF THE INVENTION

The invention relates to a method for applying a porous glass layer, as well as to a composite material with a porous glass layer.

### BACKGROUND OF THE INVENTION

The generation of porous glass layers on a substrate is known. For instance, EP 708 061 (Yazawa et al.) describes the generation of a porous glass layer by an etching method.

Known etching methods for generating porous glass layers have the disadvantage that they are very elaborate. Thus, a plurality of method steps are needed in order to generate a porous glass layer. On the other hand, the porosity factor of the glass layer cannot be adjusted arbitrarily. Furthermore, the porosity factor of an etched glass layer is usually not very homogeneous, and the porosity of the layer generally decreases with an increasing depth. It is also not possible to produce very thick layers by etching methods.

### OBJECT OF THE INVENTION

By contrast, it is an object of the invention to provide a method for applying at least one porous glass layer, which is as simple and economical as possible.

It is another object of the invention to provide a method which makes it possible to provide glass layers with different porosity factors in one apparatus. The intention is to be able to provide glass layers of different thickness and different porosity.

The porosity factor should be adjustable throughout the layer thickness, so that it is also possible to apply layers with a substantially homogeneous porosity or a porosity which deliberately changes gradually.

It is a further object of the invention to provide a composite material which is nanostructured and has optically or chemically active properties.

The object of the invention is directly achieved by a method for applying porous glass layers and by a composite material according to the independent claims.

Preferred embodiments and refinements of the invention may be found in the respective dependent claims.

### GENERAL DESCRIPTION OF THE INVENTION

The invention provides a method for applying porous glass layers, wherein a substrate and a material source are provided and a glass layer with a porosity factor of more than one percent is deposited on the substrate by means of a PVD method.

The invention furthermore provides a method for applying porous glass layers, which comprises the following steps: providing at least one substrate, providing at least one material source and depositing at least one porous glass layer. In one embodiment, the porous glass layer is deposited with a porosity factor of more than 1%. The porous glass layer is in this case preferably deposited on the substrate by means of a PVD method, in particular by means of evaporation coating.

The Inventors have discovered that it is possible to deposit porous glass layers by means of a PVD (physical vapour deposition) method. Such a PVD method can be carried out in one process step, and it is substantially less elaborate than conventional etching methods. Moreover, the porosity of the glass layer can be deliberately controlled during the PVD method.

It is thus possible to apply a glass layer with an essentially homogeneous porosity, whereas known etching methods usually have porosity factors which increase from the substrate side towards the outer side.

The porous glass layer is preferably designed as a functional layer. Inclusions of cavities in deposited glass layers are not desired according to the known prior art. The Inventors have however discovered that it is possible to provide a layer which serves as a functional layer owing to the porosity, i.e. the porosity for the first time allows particular functions of the layer which will be described in more detail below.

The invention provides for the deliberate generation of gradient layers, i.e. layers with a porosity factor which deliberately changes from the outside inwards. In particular, the invention provides for the generation of layers with a high initial porosity on the substrate side and a lower porosity on the outer side.

The method according to the invention is suitable for virtually all types of substrates; in particular, plastic substrates may also be used. By means of a PVD method, it is even possible to coat sizeable substrates such as windows, displays etc. This may preferably be carried out in continuous throughput apparatus.

A glass target is provided as the material source. The glass may for example be converted into the gas phase by evaporation coating, for example by electron beam evaporation, or by sputtering, and it is then deposited on the substrate.

The porosity factor of the layer being deposited may be controlled inter alia by means of the deposition rate and by means of the pressure in the apparatus. In general, higher deposition rates and/or a higher partial pressure in this case lead to higher porosities.

Special properties of the layer, for example adhesion on plastic or functional properties, may furthermore be adjusted by means of the composition of the residual gas.

Deposition methods by means of electron beam evaporation, which are known per se to the person skilled in the art, have the advantage that the sputtering temperatures can be kept very low and substrates made of a polymeric material may also be coated. The low thermal load due to the evaporation coating also makes it possible to employ photolithographic techniques, in particular while using a heat-sensitive photoresist. Individual layers of porous glass may therefore also be applied in a structured fashion. This comprises single or repeated conduct of the following method steps of coating a substrate with a photosensitive resist layer, photolithographically structuring the applied resist layer, coating the thus pre-structured substrate with a porous glass layer and lift-off of the resist layer. Evaporation coating, in particular electron beam evaporation, is furthermore distinguished by an increased deposition rate compared with sputtering.

The porosity factor specified in percent in the context of this application is defined as overall porosity, i.e. the numerical indication in percent concerning the proportion of the pore volume to the total volume, both the open and closed pores being included.

The integral porosity factor may for example be found by determining the layer density (for example by means of X-ray reflection experiments with grazing incidence (GIXE)), or it may be calculated from the mass per unit area of the layer (obtainable using oscillating quartz measurements during production) and the geometrical layer thickness (optically determinable), relative to the density of the compact starting material or a compact glass with a chemical composition comparable to that of the layer.

The (open) pore sizes may also be ascertained by means of diffusion experiments, the layer being exposed to tracer molecules of different size and the diffusion of these substances into the layer below a certain size being detected. Transmission or scanning electron images or light microscopy images on layer cross sections are also feasible in order to determine the pore size and distribution (open and closed).

The porosity factor may also be carried out by means of IR spectroscopy. IR spectroscopy is generally carried out in the near and medium IR range (4000 cm⁻¹ to 400 cm⁻¹), and it can provide information about the composition and structure of ODS. For example, the relative proportion of layer constituents can be determined by comparing the intensity of IR absorption bands. Another field of application for IR spectroscopy on an ODS is the detection of impurities, such as water or silanol groups, with their characteristic absorption bands at 3350 cm⁻¹ (—OH) and 3650 cm⁻¹ (hydrogen-bonded silanol groups). Via the presence of these impurities, conclusions can be drawn about the porosity of the ODS (Maissel, Glang, “Handbook of Thin Film Technology”, McGraw-Hill (1970)).

It is suspected that the porosity is due inter alia to column growth of glass layers taking place on the substrate surface, particularly at high deposition rates. The interstices between the individual columns lead to a porous structure of the glass layer.

The term glass layer in the context of the invention is also intended to mean a semicrystalline layer, i.e. a layer in which the deposited glass does not entirely have an amorphous structure

The deposition rate when applying a porous glass layer is preferably between 0.1 and 10 μm/min, particularly preferably between 0.5 and 8 μm/min and particularly preferably between 1 and 4 μm/min.

It has been found that the deposited structures become increasingly porous with deposition rates of more than 0.5 μm/min.

By means of the method according to the invention, it is thus possible to generate glass layers with a porosity of between 1 and 60%, in particular between 5 and 50%. Layers with such porosity factors are suitable for a wide range of application tasks. A layer with a porosity factor of more than 60%, however, has the disadvantage that the mechanical stability is very limited.

A substrate temperature of 120° C. is preferably not exceeded; it is even possible not to exceed substrate temperatures of 100° C. or 80° C. It is thus also possible to coat organic material, in particular OLEDs.

This is possible in particular when the porous glass layer is deposited by means of an electron beam evaporation method.

Layer thicknesses with a thickness of from 1 nm to 1000 μm are made possible according to the invention.

An almost arbitrarily thick porous layer can thus be generated, from a monolayer up to layers in the millimetre range.

A material source, from which a layer that leads at least to a binary system grows, is provided in a refinement of the invention. It has been found that both the optical and the mechanical properties of such at least binary glass layers are substantially better. It is suspected that such binary systems are less susceptible to crystallization so that semicrystalline structures, which are detrimental both for the optical and for the mechanical properties of the glass, are substantially avoided.

In particular, metal oxides are highly suitable for the formation of such a binary system.

According to a refinement of the invention, at least two different material sources are provided. It is thus possible to generate a mixed structure.

In particular, by providing two material sources whose respective deposition rates can be varied, provision is made to generate layers with a gradually changing material composition.

In a preferred embodiment of the invention, the porous glass layer is deposited in one process step. In contrast to conventional etching methods, according to the invention it is possible to generate a porous layer in a vacuum chamber in one method step. The method according to the invention is therefore substantially more economical and simpler than conventional etching methods.

In a preferred embodiment of the invention, the deposition of the at least one porous glass layer is carried out at a pressure of more than 10⁻³ mbar, preferably 10⁻² mbar. It has been found that comparatively high pressures for a PVD method lead to porous layers preferentially being deposited.

In a refinement of the invention, the at least one porous glass layer is doped at least locally in order to deliberately change the optical or other properties. Doping with extrinsic atoms may for example be achieved by co-evaporation of a doping material, in particular ⅗ elements such as aluminium, arsenic, gallium, phosphorus or antimony. Such dopings are important particularly in electrical technology for which, inter alia, porous glass layers produced by means of the method according to the invention are used.

The porous glass layer preferably has an average pore cross section of between 1 nm and 100 μm, preferably between 100 nm and 10 μm. It is possible to provide a wide spectrum of different pore cross sections for various applications. The pore cross section usually ranges within the scale of fine porosity in this case. In particular, porous glass layers with pore cross sections of from 1 nm to 10 nm may also be generated, for example for ion-selective membranes.

According to the invention the porosity of the glass layer, i.e. the porosity factor and the average pore cross section, may be controlled by means of the deposition rate, the process pressure and the substrate temperature. It has been found that higher deposition rates and higher process pressures generally lead to a higher porosity. Lower temperatures also generally lead to higher porosities.

In a refinement of the invention water vapour is added during the deposition, particularly in order to control the porosity factor. It has been shown that the porosity is substantially increased by the introduction of water vapour. It is suspected that the chemical interaction and OH groups being formed create clumps or conglomerates during the deposition, which increase the porosity factor.

As an alternative an organic substance, in particular methane, ethane or acetylene, may be added in order to increase the porosity factor. It is suspected that the incorporation of organic residue groups leads to cavities which entail an increased porosity factor.

In a refinement of the invention nanoparticles, i.e. particles with a dimension of about 1 to 10 nm, are applied as powder during the deposition. Such nanoparticles are incorporated into the glass layer being deposited, and they lead to a layer with nanoscale structuring.

In a preferred embodiment of the invention the porous glass layer forms a membrane, i.e. a porous wall for the separation of liquids or gases. In particular, by deliberately adapting the porosity factor and the average pore cross section, it is possible to produce semipermeable membranes with which substance separation is possible.

The production of membranes may in particular comprise the detachment of layers from the substrate, for example by mechanical, thermal or chemical means. The support substrate may also be dissolved or removed, for example by etching it away, in particular by means of an ion beam, chemically or by dissolving the support (for example a water-soluble support substrate in water).

Polymers in particular, especially polyethylene oxide, may be envisaged as the substrate. Owing to process temperatures lower than 80° C., it is also possible to coat such materials by means of the method according to the invention.

As an alternative, particularly in order to form electrodes, a substrate comprising a metal may also be used.

In a refinement of the invention, a chiral support material is used. A chiral membrane, which may be used to separate enantiomers, is thus radially generated.

As an alternative or in combination, chiral compounds may also be applied by evaporation coating or as powder, in order to impart chiral properties to the porous glass layer.

In a refinement of the invention, a catalytically acting substance is co-deposited. The porous glass layer thus forms a catalytically acting material, which is favoured by the large surface area of such a porous layer.

According to the invention, provision is also made to deposit crystalline segments.

In a refinement of the invention, titanium dioxide is deposited. A layer comprising titanium dioxide may, for example, be used in photochemistry. In particular, oxygen and hydrogen may be released in an aqueous environment by exposure to light. A layer comprising titanium oxide has a large surface area and effectively generates nascent oxygen which has a further oxidizing and antibacterial effect, and so that the refinement may be used inter alia for cleaning and treating water.

In general, layers with a very wide variety of compositions may be provided by co-evaporation or applying other materials as powder. In this context dyes, nanomaterials or organometallic complexes may be added, so that layers can be generated for a very wide variety of application fields.

In a refinement of the invention, the porous glass layer is impregnated with a polymer solution. The cavities thus become filled at least partially with a polymer solution. The polymer solution may itself be part of a functional layer owing to its chemical optical properties, or it may be a support for substances with chemical or optical properties.

According to the invention, provision is also made to use a monomer solution, i.e. a solution which comprises at least one monomer, the monomer or monomers not being polymerized out until they are in the layer.

Provision is also made to fill the porous glass layer with semiconducting material. During exposure to the light, electrons in the semiconducting material are released, separated at the phase boundaries and transported to the electrodes. A substrate material produced in this way may be used particularly in photovoltaics or photochemistry.

According to the invention, provision is also made to fill the porous glass layer at least partially with an electrically conductive material. Such layer systems may then be used particularly in electrical technology and electronics, for example for accumulators.

According to the invention, gradient layers with a varying porosity may be deposited. In this context, a gradient layer may be generated with a porosity factor either increasing or decreasing outwards.

Provision is however also made to deposit a layer with an alternating porosity factor. Such a layer with an alternating porosity factor may be deposited in one process step according to the invention.

In a refinement of the invention, provision is made to provide the layer with an electroluminescent material. Such electroluminescent materials may also be used for the production of light-emitting components.

According to the invention, provision is also made to use such layers with an electroluminescent material in optoelectronics.

Besides the simple producibility of such layers, the thermal load-bearing capacity of glass is a great advantage.

In a refinement of the invention, a sealing layer is applied onto the porous glass layer. Such a sealing layer may for example be a glass layer with a high density, which can likewise be applied or deposited by means of a PVD method. This may particularly readily be carried out in one process step. Thus, provision is made to modify the process parameters so that a dense layer is deposited at the end. This may be carried out in particular by reducing the deposition rate and/or reducing the pressure in the apparatus. Such a sealing layer preferably comprises a binary system and, in addition, it may be deposited by ion beam compaction which leads to a further increase in the density.

According to the invention, provision is also made to deposit a porous glass layer, impregnate it with a solution, in particular a monomer or polymer solution, and optionally seal it with a dense glass layer after drying or polymerization.

The invention furthermore relates to an alternative method for producing porous glass layers.

According to this method, at least one first substance and one second substance are provided. A composite material is then produced from the two substances. For example, the first substrate may comprise a glass which is formed with a filler as the second substance to give a composite material. According to the invention, provision is also made for a glass not to be formed until the production of the composite material. In particular, the first substance may initially be present in a crystalline form and deposited on the substrate, where it solidifies vitreously.

The second substance is finally removed at least partially, so that a porous glass layer remains.

The second substance may thus be regarded as a filler, and it is removed by a suitable method so that cavities remain. The result of this is to provide a porous glass layer. In the context of the invention, a glass layer is also intended to mean layers which also comprise non-vitreous substances besides glass. Both full removal of the second substance and partial removal of the second substance may be envisaged. In particular, provision is made to remove the second substance only partially so that, although cavities are formed, residues of the second substance still remain as a binder for individual glass particles.

This embodiment of the invention makes it possible both to form a porous glass layer on a substrate, in which case the first and second substances are for example deposited, and to produce a porous glass layer as a single layer without using a substrate.

A glass is preferably used as the first substance. It is nevertheless also possible to use a crystalline material, which does not form a vitreous structure until it is deposited on a substrate.

In order to achieve a structure of the composite material making it possible to generate a porous structure, according to the invention provision is made for the first and the at least second substance to be provided as a substance mixture, i.e. for example as a solution or a dispersion. During the production of the composite material, the substances demix at least partially by phase separation. The mixture has a structure which does not make it possible to form a porous glass layer owing to the fine distribution of the first substance. During the production of the composite material, i.e. for example during the deposition of a layer, these substances demix so as to provide a structure with sufficiently large inclusions of a filler. The filler is then removed, and a porous glass layer remains. In the context of the invention, the composite material could thus still be regarded as a mixture, the inclusions of the second substance on average only occupying volume in the first substance so as to make it possible to produce a layer with a measurable porosity factor.

As an alternative or in combination, according to the invention provision is made for the substances not to be partially demixed until after the production of the composite material. This is carried out in particular by the action of electromagnetic radiation, in particular by the action of light or by the action of electrically charged particles, in particular by the action of ions. This procedure has the advantage that the degree of demixing, and therefore the pore size, can be influenced by means of the duration of the action of the electromagnetic radiation. As an alternative or in combination, the demixing may also be carried out by heating.

In another embodiment of the invention, at least one of the substances is provided as granules. The porosity factor and the porosity distribution of the porous glass layer can be adjusted by means of the particle size and the particle size distribution. According to the invention, provision is made either to provide the filler or a glass as granules, or to provide the filler and glass as granules.

By means of granules, it is possible to generate porous glass layers with comparably large pores.

In a preferred embodiment of the invention, the production of the composite material comprises the pressing of granules. This procedure is suitable in particular when glass granules are provided and the filler is simultaneously intended to serve as an adhesive for the individual glass grains. The pressing leads to a firm connection at the contact points of the individual glass grains, and the residues of the filler preferentially remain at these contact points when the filler is removed.

In a particularly preferred embodiment of the invention, at least some glass granules are sintered during the production of the composite material. In particular, provision is made for a mixture of glass granules and a salt to be subjected to a sintering process. The sintering process is in this case preferably controlled so that the glass grains are essentially connected to one another at their contact points. The salt may then readily be dissolved and a porous glass layer remains.

Sodium chloride crystals, which readily dissolve with water as a solvent, are intended in particular as the salt.

The size of the salt crystals will be adapted to the desired pore size or to the desired pore size distribution.

As an alternative to dissolving the second substance, i.e. the filler, the second substance is etched away at least partially in an etching bath. Etching methods also make it possible to use mixtures of two different glasses, if an etchant which essentially acts only on one component is employed.

The invention furthermore relates to a composite material which comprises a deposited glass layer with a porosity factor of more than 1% or a layer produced by means of a method according to the invention. Such a composite material is distinguished by a high robustness and, in particular, it is substantially easier to produce by means of one of the methods according to the invention than conventional composite materials with a porous layer.

The invention furthermore concerns a composite material which comprises at least one deposited porous glass layer. In one embodiment, the deposited porous glass layer has a porosity factor of more than 1%. The porous glass layer is preferably deposited by means of a PVD method, in particular by means of evaporation coating.

The composite substrates according to the invention are producible, in particular produced, by a method for applying porous glass layers or by a method for applying glass layers or by a method for producing porous glass layers.

According to the invention, the composite material may comprise either a single porous glass layer or a substrate, which is covered with a porous glass layer according to the invention. The term composite material is thus intended to mean any material which comprises at least two functional components.

A composite material according to the invention may be used for a wide range of applications.

Membranes may be provided by means of the invention. In the first embodiment of the invention, the porous glass layer is in this case deposited on a support substrate, and the support substrate is then thinned and at least partially removed. Both chemical and mechanical methods are suitable for the thinning. Thus, it is possible to use a substrate which can be dissolved or etched away.

In the second embodiment of the invention, a substrate is omitted so that its removal is obviated.

For example, according to the invention provision is made to use the composite material in electrochemistry. The material is in this case distinguished by a high corrosion resistance even at elevated temperatures, and by mechanical robustness.

A porous glass layer has good wetting properties, in particular for water-soluble compounds.

When deposited on a polymeric support material or a metal substrate, a membrane which is formed from a composite material according to the invention may be used in fuel cells.

In contrast to conventional polymer membranes, such a membrane with a glass layer has the advantage that it is substantially less susceptible to an ageing process.

By suitably adjusting the porosity, it is possible to generate ion-selective membranes. For example, provision is made to use an ion-selective membrane for accumulators, in particular for lithium ion cells. The transport medium in this case comprises a polymer, in particular a polyethylene oxide. Extremely flat rechargeable cells can be produced owing to the small layer thicknesses which are possible.

Ion-selective electrodes are moreover required for a wide range of other applications. The method according to the invention in this case has the advantage that the porosity factor can be adjusted virtually arbitrarily.

The composite material according to the invention is also intended for catalysts. For example, membranes which are catalytically active may be generated by co-evaporation of catalytic substances.

A multilayer system may in this case be employed, in the layers of which various reaction materials are provided. The effect of the separation of the sites of a catalytic reaction, due to the pores, is that undesired side reactions can be substantially prevented.

The evaporation-coated glass layers according to the invention may furthermore be used for substance separation. Thus, provision is made for such layers to be used as a molecular sieve or molecular filter. It is possible to adjust the pore size to a very narrow range. Individual molecules, ions, etc. may thus be removed selectively. It is advantageous that even strongly corrosive or chemically aggressively acting substances can readily be separated by a composite material according to the invention.

Chiral membranes for the separation of enantiomers may be generated by introducing chiral substances into the substrate or into the porous glass layer. As an alternative or in addition, at least one chiral substance may be introduced into the porous layer, for instance by applying chiral material as powder.

The composite material according to the invention may also be employed for the separation of gases, particularly in the field of osmosis and reverse osmosis. Owing to the high mechanical stability, such processes can be operated at higher pressures than in the case of conventional, purely polymeric materials.

The composite material according to the invention may also be employed in the medical field. It has a high biocompatibility, it is not attacked by body cells and it can therefore be used both for medical applications and outside the body. In particular, such a material is intended to be used for dialysis. The composite material according to the invention is also intended to be employed for the production of implants. For example, the layer of porous glass may in this case be used as a support material in which biological structures can grow.

The composite material according to the invention is furthermore intended to be used in optoelectronics. It is possible to generate very thin layers which are wavelength-selective, i.e. they affect only particular wavelengths for example by scattering or interference effects.

By means of process parameters and by doping and co-evaporation of other materials, layers with a very wide variety of optical properties can be generated and for example optical filters, mirror switches and cavities may readily be produced. Such layers may also be used for optical data storage.

Porous evaporation-coated glass allows, in particular, a straightforward method for producing photonic crystals or use of the composite substrate according to the invention in photonic applications. Photonic applications comprise for example optical switches or optical filters.

Optical switches represent a component in optical networks which, for example, switch light signals between various optical waveguides without the signals previously having to be converted into electrical signals.

Photonic crystals are distinguished in particular by a refractive index periodically varying spatially. By means of the method according to the invention, the periodic properties of such a photonic crystal can be achieved reproducibly. In particular, the properties of the photonic crystals may be controlled by the size of the pores. The pores may also be filled with selected materials. Possible materials may in this case be ferroelectric, ferromagnetic and/or polymeric materials. The properties of the photonic crystals may be controlled by the size of the pores and/or the materials for filling the pores. The behaviour of the structure may then be controlled by means of external electrical, magnetic and/or optical fields.

Glass with the aforementioned materials as partners may be deposited by the evaporation coating technique, preferably in a structured fashion, in order to achieve the desired optical effect. Further examples of the aforementioned partners comprise wavelength-dependent nanoparticles or dyes. An advantage in this case is the straightforward process control owing to the possibility of simultaneously co-evaporating the partners and controlling the pore size.

According to the invention, the porous glass layers according to the invention are also intended in particular as interference and blooming layers. A porous glass layer has a lower refractive index than a compact glass layer. For normal light incidence, the thickness of the layer is preferably about ¼ of the wavelength to be bloomed. Thicker layers are to be used for oblique incidence.

By means of a corresponding masking technique, it is likewise possible to produce lenses, DOEs or Fresnel lenses from differently dense material.

By embedding dyes, nanomaterials or semiconductors, the composite material according to the invention is also intended to be used for example as a matrix in photovoltaics, electroluminescence, photoluminescence or photochemistry.

According to the invention, the substances required for generating a photochemically or electrochemically active layer may be co-evaporated in one step and deposited in a distributed way in and over the porous glass layer. The layers thus formed have a very high surface area. By means of photochemical reduction or oxidation processes, for example, liberated gases may deliberately be filtered out through a porous glass layer.

The use of a composite material according to the invention, particularly with a metal substrate, is also intended in electrical technology.

A particular advantage of the porous glass layer in this case is that glass has a high breakdown strength.

The invention therefore also relates to an ion-selective electrode, an accumulator, a catalyst material, a filter, a support material for biological structures, an implant for human or animal bodies, optical data storage, an optical electronic component, an electrotechnical component and a capacitor, in each case comprising at least one composite material according to the invention.

The invention furthermore relates to an anti-mist layer or anti-frost layer. The Inventors have found that by means of a method according to the invention, it is possible to form hydrophilic layers by which condensation of water or formation of ice on a surface can be prevented at least for a limited period of time. The water is in this case absorbed by the porous layer, and released after the support substrate has been heated to the ambient temperature or when the temperatures of the surface and the environment have become balanced. In particular owing to its thermal stability, such an anti-mist layer or anti-frost layer is suitable in particular for a wide range of applications, for example vehicle windows, visual aids or refrigerators.

The anti-mist layer or anti-frost layer may be improved by nanoparticles, in particular by silicon nanoparticles applied as powder.

The hydrophilic property may furthermore be improved by organic polymers, in particular a polyurethane or a polyvinyl alcohol. In a particular embodiment of the invention, a porous glass layer is impregnated with an organic polymer. The polymer is then allowed to run off, so that the pores are at least partially opened again but are wetted with the polymer. The polymer is then cured. To this end, when employing a drying method, a polymer solution may be used. As an alternative, the polymer is cured by polymerization which, for example, may be generated by exposure to UV light. This provides a porous glass layer which has a polymer coating.

Further applications of porous glass layers are described in DE 3222675, EP 310911, DE 3733636, EP 389896, DE 3909341, DE 3909341, DE 4005366, DE 4111879, EP 508343 and WO 05042798, the entire disclosure content of which is hereby incorporated.

It is to be understood that the respective components may also form the substrate of the composite material and thus be part of such a composite material.

### GENERAL DESCRIPTION OF THE DRAWINGS

The invention will be explained in more detail below with the aid of the drawings FIG. 1 to FIG. 12.

FIG. 1 schematically shows an exemplary embodiment of a composite material according to the invention.

FIG. 2 schematically shows another exemplary embodiment of a composite material according to the invention.

FIG. 3 schematically shows a PVD apparatus for carrying out a method according to the invention.

FIG. 4 schematically shows a data store according to the invention.

FIG. 5 schematically shows an electrode according to the invention.

FIG. 6 schematically shows an implant according to the invention.

FIG. 7 schematically shows a flow chart of a method according to the invention.

FIGS. 8 and 9 schematically show the production of a porous glass layer by means of phase separation.

FIGS. 10 to 12 schematically show the steps for producing a porous glass layer by another alternative method.

FIGS. 13.a to 13.c schematically show the production of a porous glass layer structured by way of example.

### DETAILED DESCRIPTION OF THE DRAWINGS

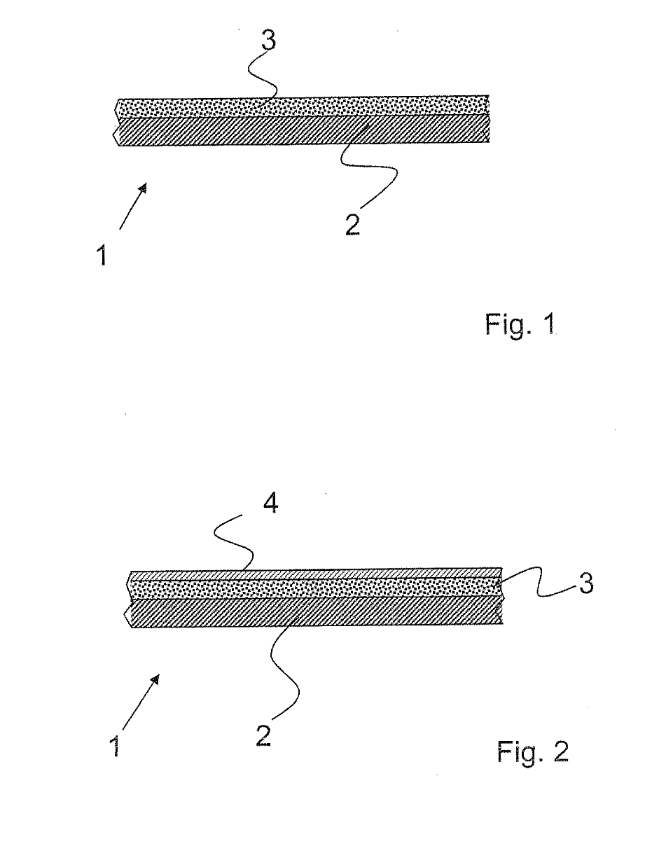

FIG. 1 schematically shows an exemplary embodiment of a composite material 1 according to the invention. The composite material 1 in this exemplary embodiment comprises a substrate 2, here configured as a plastic substrate. A porous glass layer 3 is deposited on the upper side of the substrate 2 by means of a PVD method. The porous glass layer 3 in this exemplary embodiment has a thickness of between 100 and 600 nm. The composite material 1 is suitable for a multiplicity of applications.

FIG. 2 shows another exemplary embodiment of a composite material 1 according to the invention. The composite material 1 comprises a substrate 2 made of a polymeric material. A 100 to 500 nm thick porous glass layer 3 with a porosity factor of between 10 and 30% was deposited onto the substrate by means of an electron beam evaporation method. The porous glass layer 3 was then sealed with a sealing layer 4. The sealing layer in this exemplary embodiment was applied using the same material source (not shown) as the porous glass layer 3. In order to achieve a dense sealing layer 4, a deposition rate of the apparatus (not shown) was to this end lowered and the pressure in the apparatus was reduced by a factor of about 10. The sealing layer 4 was also compacted further by means of an ion beam compaction method. The sealing layer 4 could thus be deposited in one process step, although it has no measurable porosity factor.

Instead of the ion beam, the layers could also be deposited by plasma action and/or plasma enhancement. A compacted layer which has only an extremely small porosity, or no measurable porosity, can thus be deposited.

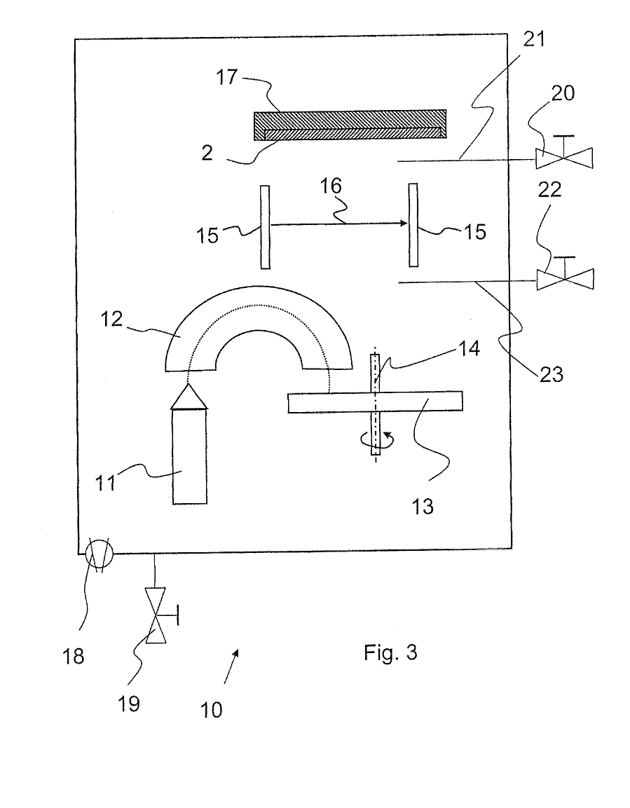

FIG. 3 schematically shows a PVD apparatus 10 for carrying out the method according to the invention, which is also suitable for producing a composite material according to the invention. The substrate 2, which may be arranged in a substrate holder 17, is coated by means of an electron beam method in the PVD apparatus 10.

To this end, an electron source 11 is arranged in the apparatus 10. By means of a deviating magnet 12, the electron beam output by the electron source 11 is directed onto a disc-shaped target 13. In this version, the target 13 can be rotated about a rotation axis 14 in order to achieve a maximally uniform deposition rate.

A disc of borosilicate glass with a low melting point, which in this exemplary embodiment also comprises a metal oxide and thus forms a binary system in the deposited state on the substrate 2, is provided as the target 13 or material source here.

The target 13 is evaporated by the electron beam and is deposited on the substrate 2. In order to deflect secondary ions, two electrodes 15, at which a voltage can be applied and an electric field can be generated, are also arranged between the substrate 2 and the target 13. The direction of the field is marked by an arrow 16.

The apparatus is evacuated by means of a pump 18. The apparatus pressure can be regulated by means of a control valve 19.

The porosity of the layer deposited on the substrate 2 can be controlled directly by means of the pump 18 and the control valve 19.

For further control, a supply for water vapour 23 is also provided in the PVD apparatus 10. The water vapour supply can likewise be controlled by means of a control valve 22. As an alternative or in addition, organic gases may also be supplied.

During the deposition, the effect of the supplied water vapour is that a substantially higher porosity factor is obtained.

The apparatus 10 furthermore comprises a supply for solid particles 21, which can likewise be regulated by means of a control valve 20.

The solid particles may be supplied to the valve in a fluid flow, for example an argon atmosphere. They may for example be nanoparticles, which can provide a nanostructured layer on the substrate 2.

Optically active substances, by which an optical functional layer is deposited on the substrate, may be supplied as an alternative.

Glasses which have the following composition ranges in percent by weight have proven particularly suitable as an evaporation-coating glass for a method of applying porous glass layers according to the invention:

| Component | Glass range | Glass range 2 |
|---|---|---|
| SiO₂ | 75-85 | 65-75 |
| B₂O₃ | 10-15 | 20-30 |
| Na₂O | 1-5 | 0.1-1 |
| Li₂O | 0.1-1 | 0.1-1 |
| K₂O | 0.1-1 | 0.5-5 |
| Al₂O₃ | 1-5 | 0.5-5 |

Preferred evaporation-coating glasses from this group are glasses with the following composition in percent by weight:

| Component | Glass 1 | Glass 2 |
|---|---|---|
| SiO₂ | 84.1% | 71% |
| B₂O₃ | 11.0% | 26% |
| % Na₂O | ≈2.0% | 0.5% |
| Li₂O | ≈0.3% | 0.5% |
| K₂O | ≈0.3% | 1.0% |
| A1₂O₃ | ≈2.6% | 1.0% |

It should be pointed out that the said compositions do not refer to the deposited layers; rather, the composition changes during evaporation coating.

The preferably usable glasses have, in particular, the properties listed in the following table:

| Properties | Glass 1 | Glass 2 |
|---|---|---|
| a₂₀₋₃₀₀ [10⁻⁶K⁻¹] | 2.75 | 3.2 |
| Density (g/cm³) | 2.201 | 2.12 |
| Transformation point [° C.] | 562° C. | 742° C. |
| Refractive index | n_{D} = 1.469 | 1.465 |
| Water resistance class according to ISO | 1 | 2 |
| 719 | | |
| Acid resistance class according to DIN | 1 | 2 |
| 12 116 | | |
| Alkali resistance class according to | 2 | 3 |
| DIN 52322 | | |
| Dielectric constant å (25° C.) | 4.7 | 3.9 |
| | (1 MHz) | (40 GHz) |
| tand (25° C.) | 45*10⁻⁴ | 26*10⁻⁴ |
| | (1 MHz) | (40 GHz) |

The evaporation-coating glass type 8329 from Schott, which has the following composition in percent by weight, has proven particularly suitable for the evaporation coating of porous glass layers:

$$\begin{matrix}{SiO}_{2} 84.1 \% \\ {B}_{2} {O}_{3} 11.0 \%\end{matrix} \\ \begin{matrix}{Na}_{2} O \approx 2.0 \% \\ {K}_{2} O \approx 0.3 \% \\ {Li}_{2} O \approx 0.3 \%\end{matrix} \} 2.3 \% ( in the layer ⇒ 3.3 \% )$$

$${Al}_{2} {O}_{3} \approx 2.6 \% ( in the layer ⇒ 0.5 \% )$$

The electrical resistance of the starting material is approximately 10¹⁰ Ω/cm (at 100° C.),

In the pure form, this glass furthermore has a refractive index of about 1.470.

The dielectric constant ∈ is about 4.8 (at 25° C., 1 MHz), and tgδ is about 45×10⁻⁴ (at 25° C., 1 MHz). The evaporation process and the differing volatility of the components of the system lead to slightly different stoichiometries between the target material and the evaporation-coated material. The deviations in the evaporation-coated layer are indicated in brackets.

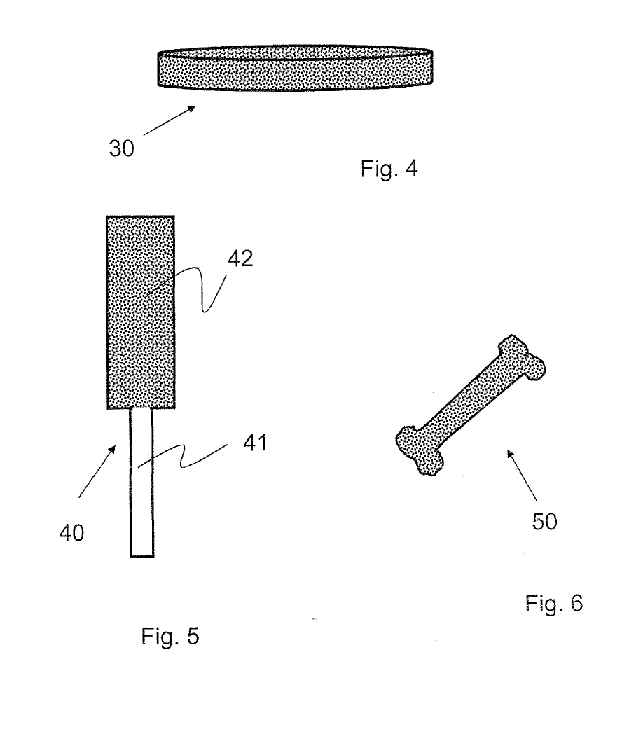

FIG. 4 schematically shows a data store 30 according to the invention. It is a substrate which is coated with a porous glass layer having optical properties. Disk storage is represented here, the structuring of which is not represented in further detail.

FIG. 5 schematically shows an electrode according to the invention 40. The electrode comprises a metal substrate 41, which is coated on the electrode plate with a porous glass layer. Such an electrode 40 may, for example, be used for a high-performance capacitor (not shown).

FIG. 6 schematically shows an implant according to the invention 50. The implant 50 in this case is a bone implant, which is coated with a porous glass layer. The porous glass layer 50 increases the mechanical stability of the surface and simultaneously serves as a support substrate for a material intrinsic to the body.

Such an implant thus grows better in the body, and the porous glass layer has a better bioresistance.

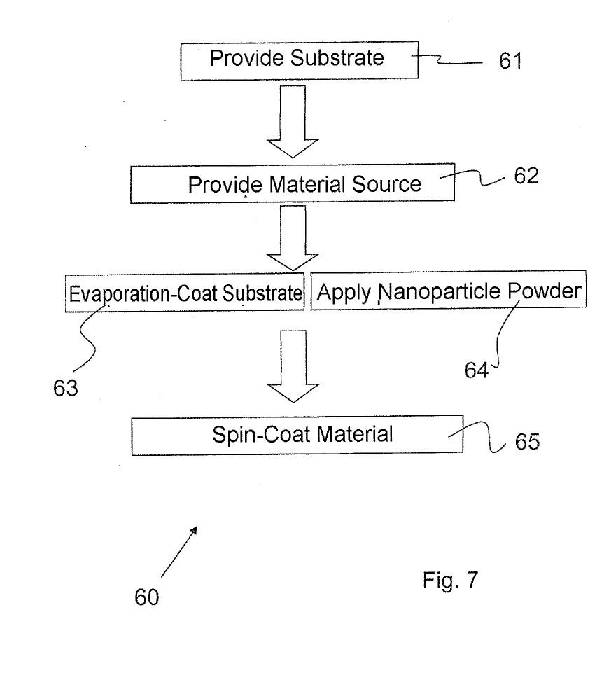

FIG. 7 schematically shows a flow chart 60 of a method according to the invention. According to the method, a substrate 61 is provided. A material source 62 is then provided. A porous glass layer 63 is vapour-deposited onto the substrate, and nanoparticles are applied as powder 64. This provides a substrate with a nanostructured surface, then the substrate is impregnated 65 by means of a coating method from the liquid phase, for example spin coating, dip coating methods or a printing method, for example inkjet printing or screen printing. For example, optically active materials may be introduced into the substrate by means of a spin coating method. The spin coating solution may comprise a polymer and a solvent, and thus enter into a firm bond with the porous glass layer by evaporation of the solvent.

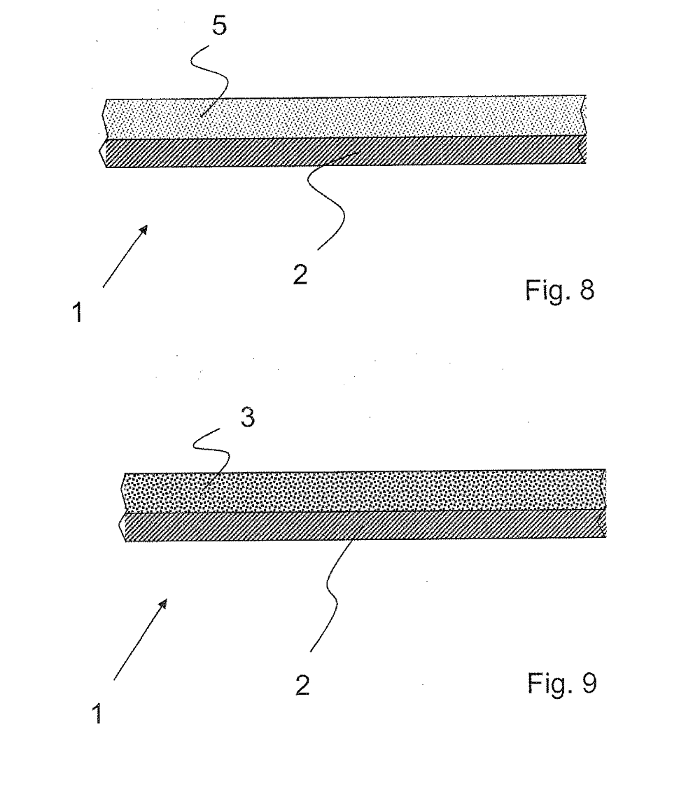

FIGS. 8 and 9 schematically show the production of a porous glass layer by means of phase separation. As represented in FIG. 8, a composite material 1 which comprises a substrate 2 and a two-component layer 5 is provided. The two-component layer 5 comprises a mixture of two different substances.

As represented in FIG. 9, the composite material 1 has been exposed to UV irradiation. The two substances have partially demixed owing to the irradiation. After the removal of one component, a porous glass layer 3 remains.

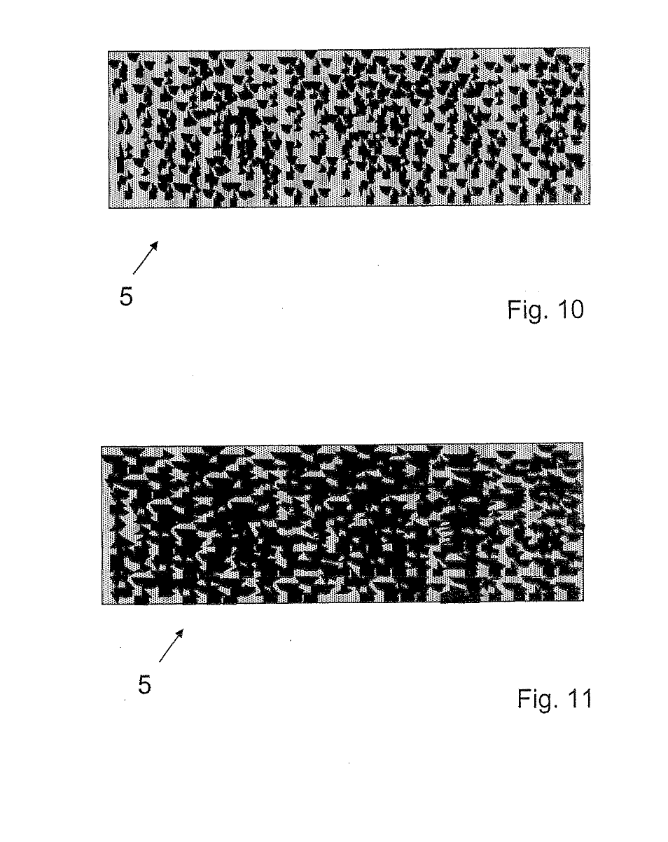

An alternative embodiment of a method for producing a porous glass layer will be shown schematically with the aid of FIGS. 10 to 12.

FIG. 10 shows a two-component layer 5, which is pressed from glass granules and salt granules. The salt grains are represented as black particles.

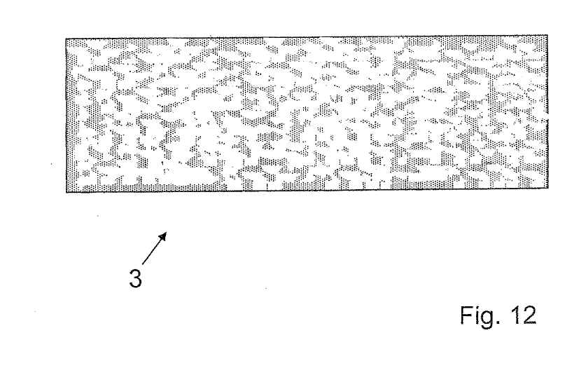

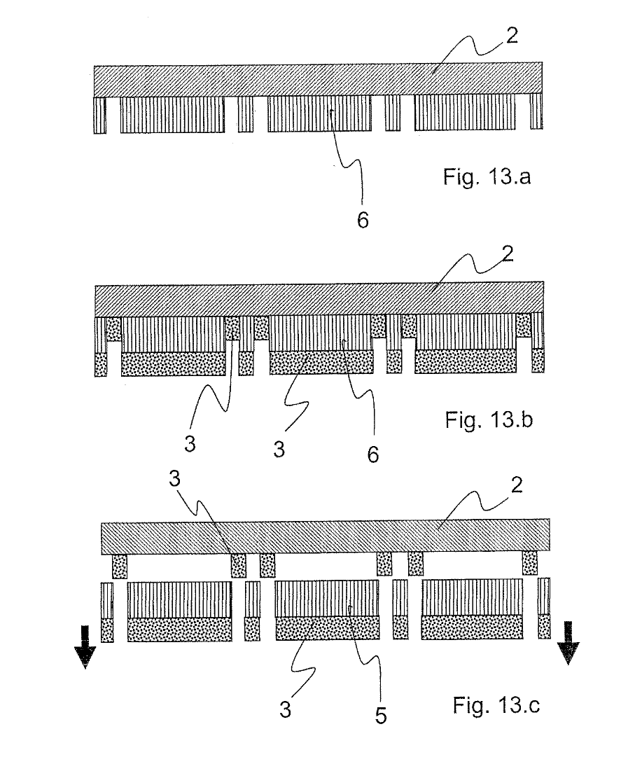

FIG. 11 shows the two-component layer 5, after it has been subjected to a sintering process. The individual glass and salt particles are fused together at their interfaces. The salt is subsequently dissolved in water, so that a porous glass layer remains, as represented schematically in FIG. 12. FIGS. 13.a to 13.c show the production of a structured porous glass layer 3. A mask 6, for example in the form of a photoresist, is applied and photolithographically structured by a method known to the person skilled in the art on the side of the substrate 2 which is to be structured. The structuring corresponds to the negative image of the structure to be generated. A porous glass layer 3 is deposited on the structured side the substrate 2. Inside the holes of the mask 6, a glass layer 3 is deposited directly onto the substrate 2. The porous glass layer 3 may, for example, be applied by means of electron beam evaporation or plasma ion beam-enhanced electron beam evaporation. The regions of the deposited glass layer 3 which lie on the mask 6 are subsequently removed by means of lift-off. To this end, for example, the photoresist is dissolved in acetone. The glass layer 3 deposited in the regions of the holes of the mask forms the desired positive structure on the substrate.

It is to be understood that the invention is not restricted to the exemplary embodiments described here, rather that any combination of features which the person skilled in the art might deem expedient is also the subject-matter of the invention.

### LIST OF REFERENCES

1 composite material
2 substrate
3 porous glass layer
4 sealing layer
5 two-component layer
6 mask
10 PVD apparatus
11 electron source
12 deviating magnet
13 target
14 rotation axis
15 electrode
16 arrow
17 substrate holder
18 pump
19 control valve
20 control valve
21 solid particle supply
22 control valve
23 water vapour supply
30 optical data storage
40 electrode
41 metal substrate
42 electrode plate
50 implant
60 flow chart
61 provide substrate
62 provide material source
63 evaporation-coat substrate
64 apply nanoparticle powder
65 spin-coat material

1. Method for applying porous glass layers, the method comprising:
providing at least one substrate,
providing at least one material source, and
depositing at least one glass layer with a porosity factor of more than 1% on the substrate by means of a physical vapor deposition method.

2. Method for applying porous glass layers according to claim 1, characterized in that the deposition rate is between 0.1 and 10 μm/min.

3. Method for applying porous glass layers according to claim 1, characterized in that the porosity factor of the at least one porous glass layer lies between 1% and 60%.

4. Method for applying porous glass layers according to claim 1, characterized in that a substrate temperature of 120° C.; is not exceeded.

5. Method for applying porous glass layers according to claim 1, characterized in that the porous glass layer is at least partially deposited by means of electron beam evaporation.

6. Method for applying porous glass layers according to claim 1, characterized in that a layer with a thickness of between 1 nm and 1000 μm is deposited.

7. Method for applying porous glass layers according to claim 1, characterized in that at least one material source, which leads to a layer that comprises at least a binary system, is provided.

8. Method for applying porous glass layers according to claim 1, characterized in that a material source which deposits a metal oxide is provided.

9. Method for applying porous glass layers according to claim 1, characterized in that at least two different material sources are provided.

10. Method for applying porous glass layers according to claim 1, characterized in that the porous glass layer is deposited in one process step.

11. Method for applying porous glass layers according to claim 1, characterized in that the at least one porous glass layer is deposited at a pressure of more than 10⁻³ mbar.

12. Method for applying porous glass layers according to claim 1, characterized in that the at least one porous glass layer is at least locally doped.

13. Method for applying porous glass layers according to claim 1, characterized in that a porous glass layer with an average pore cross section of between 1 nm and 100 μm is deposited.

14. Method for applying porous glass layers according to claim 1, characterized in that the porosity of the glass layer is controlled by means of the deposition rate.

15. Method for applying porous glass layers according to claim 1, characterized in that the porosity of the at least one glass layer is controlled by means of the substrate temperature and/or the process temperature.

16. Method for applying porous glass layers according to claim 1, characterized in that the porosity of the at least one glass layer is controlled by means of the process pressure.

17. Method for applying porous glass layers according to claim 1, characterized in that water vapour is added when depositing the porous glass layer.

18. Method for applying porous glass layers according to claim 1, characterized in that at least one volatile organic or inorganic substance is added when depositing the porous glass layer.

19. Method for applying porous glass layers according to claim 1, characterized in that nanoparticles are added during the deposition of the at least one porous glass layer.

20. Method for applying porous glass layers according to claim 1, characterized in that the at least one porous glass layer forms a membrane.

21. Method for applying porous glass layers according to claim 1, characterized in that the method comprises the detachment of layers from the substrate and/or removal, dissolving or thinning of the substrate.

22. Method for applying porous glass layers according to claim 1, characterized in that a polymer is provided as the substrate.

23. Method for applying porous glass layers according to claim 1, characterized in that a substrate comprising at least one metal is provided.

24. Method for applying porous glass layers according to claim 1, characterized in that a chiral support material is provided as the substrate and/or at least one chiral substrate is introduced into the porous layer.

25. Method for applying porous glass layers according to claim 1, characterized in that the at least one catalytically acting substance is co-deposited.

26. Method for applying porous glass layers according to claim 1, characterized in that crystalline segments are deposited.

27. Method for applying porous glass layers according to claim 1, characterized in that TiO₂ is deposited.

28. Method for applying porous glass layers according to claim 1, characterized in that the porous glass layer is impregnated with a polymer solution.

29. Method for applying porous glass layers according to claim 1, characterized in that the porous glass layer is impregnated with at least one substance by means of a coating method from the liquid phase or a printing method.

30. Method for applying porous glass layers according to claim 1, characterized in that the porous glass layer is at least partially filled with a semiconductor material.

31. Method for applying porous glass layers according to claim 1, characterized in that the porous glass layer is at least partially filled with an electrically conductive material.

32. Method for applying porous glass layers according to claim 1, characterized in that a gradient layer with varied porosity is deposited.

33. Method for applying porous glass layers according to claim 1, characterized in that an electroluminescent material is deposited.

34. Method for applying porous glass layers according to claim 1, characterized in that a sealing layer is applied onto the at least one porous glass layer.

35. Method for applying porous glass layers according to claim 34, characterized in that the sealing layer is applied by means of a physical vapor deposition method.

36. Method for applying porous glass layers according to claim 34, characterized in that a glass layer is deposited in one process step as the sealing layer.

37. Method for applying porous glass layers according to claim 34, characterized in that the sealing layer comprises a binary system.

38. Method for applying porous glass layers according to claim 34, characterized in that a sealing layer is deposited by ion beam compaction.

39. Method for applying porous glass layers according to claim 34, characterized in that a sealing layer is deposited by plasma action and/or plasma enhancement.

40. Method for applying porous glass layers according to claim 1, characterized in that a glass, which comprises at least one of the following substances or a mixture of a plurality or all of the following substances in percent by weight, is provided as the material source:

| | |
|---|---|
| SiO₂ | 65-85 |
| B₂O₃ | 10-30 |
| Alkali metal oxide | 0.1-7 |
| Al₂O₃ | 0.5-5 |

41. Method for applying porous glass layers according to claim 1, characterized in that a glass, which comprises at least one of the following substances or a mixture of a plurality or all of the following substances in percent by weight, is provided as the material source:

| | |
|---|---|
| SiO₂ | 75-85 |
| B₂O₃ | 10-15 |
| Na₂O | 1-5 |
| Li₂O | 0.1-1 |
| Al₂O₃ | 1-5 |

42. Method for applying porous glass layers according to claim 1, characterized in that a glass, which comprises at least one of the following substances or a mixture of a plurality or all of the following substances in percent by weight, is provided as the material source:

| | |
|---|---|
| SiO₂ | 65-75 |
| B₂O₃ | 20-30 |
| Na₂O | 0.1-1 |
| Li₂O | 0.1-1 |
| K₂O | 0.5-5 |
| Al₂O₃ | 0.5-5 |

43. Method for applying glass layers, comprising: the steps
providing at least one substrate,
providing at least one material source, and
depositing at least one porous glass layer.

44. Method for applying glass layers according to the claim 43, characterized in that the porous glass layer is deposited with a porosity factor of more than 1%.

45. Method for applying glass layers according to claim 43, characterized in that the porous glass layer is deposited on the substrate by means of a physical vapor deposition method.

46. Method for applying glass layers according to claim 1, characterized in that the porous glass layer is deposited on the substrate by means of evaporation coating.

47. Method for applying glass layers according to claim 2, characterized in that the porosity factor of the at least one porous glass layer lies between 1% and 60%.

48. Method for producing porous glass layers, the method comprising:
providing a first substance,
providing at least one second substance,
producing a composite material from the first and at least second substance, the composite material comprising a glass, and
at least partially removing the second substance, so that a porous glass layer remains.

49. Method for producing porous glass layers according to claim 48, characterized in that the first substance is a glass.

50. Method for producing porous glass layers according to claim 48, characterized in that the first and the at least second substance are provided as a substance mixture, and the substances at least partially demix by phase separation during the production of the composite material.

51. Method for producing porous glass layers according to claim 48, characterized in that the first and the at least second substance are provided as a substance mixture, and the substances at least partially demix after the production of the composite material.

52. Method for producing porous glass layers according to claim 51, characterized in that the substances are demixed by the action of electromagnetic radiation.

53. Method for producing porous glass layers according to claim 48, characterized in that at least one of the substances is provided in the form of granules.

54. Method for producing porous glass layers according to claim 53, further comprising pressing the granules.

55. Method for producing porous glass layers according to claim 53, further comprising sintering glass granules.

56. Method for producing porous glass layers according to claim 48, characterized in that the second material comprises a soluble substance or consists of a soluble substance.

57. Method for producing porous glass layers according to claim 48, characterized in that the second material comprises crystals or molecule aggregates.

58. Method for producing porous glass layers according to claim 57, characterized in that the size of the crystals or the molecule aggregates is adapted to the desired pore size or the desired pore size distribution.

59. Method for producing porous glass layers according to claim 48, characterized in that the second substance is at least partially removed by dissolving in a solvent.

60. Method for producing porous glass layers according to claim 59, characterized in that water or organic solvents are used as the solvent.

61. Method for producing porous glass layers according to claim 48, characterized in that the second substance is at least partially etched away in an etching bath.

62. Composite material comprising
at least one porous glass layer deposited by means of a physical vapor deposition method.

63. Composite material according to claim 62, characterized in that the composite material comprises a substrate.

64. Composite material according to claim 62, characterized in that the porous glass layer is designed as a functional layer.

65. Composite material according to claim 62, characterized in that the porosity of the porous glass layer lies between 1% and 60%.

66. Composite material according to claim 62, characterized in that the porosity factor of the layer changes by less than 50% over the layer thickness.

67. Composite material according to claim 62, characterized in that the porous glass layer is essentially homogeneous.

68. Composite material according to claim 62, characterized in that the porosity factor of the porous glass layer changes gradually and/or in an alternating fashion.

69. Composite material according to claim 62, characterized in that the porous glass layer has a thickness of between 1 nm and 1000 μm.

70. Composite material according to claim 62, characterized in that the porous glass layer comprises at least a binary system.

71. Composite material according to claim 62, characterized in that the porous glass layer comprises at least one metal oxide.

72. Composite material according to claim 62, characterized in that the one porous glass layer is at least locally doped.

73. Composite material according to claim 62, characterized in that the porous glass layer has pores with an average cross section of between 1 nm and 100 μm.

74. Composite material according to claim 62, characterized in that the composite material comprises a substrate which comprises a polymer.

75. Composite material according to claim 62, characterized in that the composite material comprises a substrate which comprises at least one metal.

76. Composite material according to claim 62, characterized in that the composite material comprises a substrate which comprises a chiral support material.

77. Composite material according to claim 62, characterized in that the porous glass layer comprises at least one chiral substance.

78. Composite material according to claim 62, characterized in that the support material comprises at least one catalytically acting substance.

79. Composite material according to claim 62, characterized in that the porous glass layer has an optical effect.

80. Composite material according to claim 62, characterized in that the porous glass layer is configured wavelength-selectively.

81. Composite material according to claim 62, characterized in that the porous glass layer comprises at least one optically active substance.

82. Composite material according to claim 62, characterized in that the porous glass layer comprises TiO₂.

83. Composite material according to claim 62, characterized in that the porous glass layer comprises at least one nanomaterial.

84. Composite material according to claim 62, characterized in that the porous glass layer has nanostructuring.

85. Composite material according to claim 62, characterized in that the composite material has a sealing layer.

86. Composite material according to claim 85, characterized in that the sealing layer has a porosity factor of less than 1.0%.

87. Composite material according to claim 85, characterized in that the sealing layer comprises an at least binary substance system.

88. Composite material according to claim 62, characterized in that the sealing layer comprises a metal oxide.

89. Composite material producible by a method for producing porous glass layers according to claim 48, comprising at least one deposited porous glass layer.

90. Composite material according to claim 62, characterized in that the deposited porous glass layer has a porosity factor of more than 1%.

91. Composite material according to claim 62, characterized in that the porous glass layer is deposited by means of a physical vapor deposition method.

92. Composite material according to claim 62, characterized in that the porous glass layer is deposited by means of evaporation coating.

93. Composite material according to claim 63, characterized in that the porous glass layer is designed as a functional layer.

94. Ion-sensitive electrode, comprising a composite material according to claim 62.

95. Accumulator, comprising a composite material according to claim 62.

96. Catalyst material, comprising a composite material according to claim 62.

97. Filter comprising a composite material according to claim 62.

98. Lens, Fresnel lens or diffractive optical element, comprising a composite material according to claim 62.

99. Support material for biological structures, comprising a composite material according to claim 62.

100. Implant for human or animal bodies, comprising a composite material according to claim 62.

101. Optical data storage, comprising a composite material according to claim 62.

102. Optoelectronic component, comprising a composite material according to claim 62.

103. Photonic crystal, comprising a composite material according to claim 62.

104. Photonic component, comprising a composite material according to claim 62.

105. Electrotechnical or electrochemical component, comprising a composite material according to claim 62.

106. Capacitor, comprising a composite material according to claim 62.

107. Blooming layer, producible by a method according to claim 48.

108. Membrane, producible by a method according to claim 48.

109. Anti-mist layer and/or anti-frost layer, producible by a method according to claim 48.

110. Anti-mist layer and/or anti-frost layer according to claim 109, comprising nanoparticles.

111. Anti-mist layer and/or anti-frost layer according to claim 109, further comprising at least one organic polymer.
